(19) United States
(12) Patent Application Publication
(10) Pub. No.: US 2007/0131938 A1
(43) Pub. Date: Jun. 14, 2007

(54) Merged and Isolated Power MESFET Devices

(75) Inventor: Richard K. Williams, Sunnyvale, CA (US)

Correspondence Address: ADVANCED ANALOGIC TECHNOLOGIES, 830 EAST ARQUES AVE, SUNNYVALE, CA, 94085, US

(73) Assignee: ADVANCED ANALOGIC TECHNOLOGIES, INC., Sunnyvale, CA (US)

(21) Appl. No.: 11/307,204

(22) Filed: Jan. 26, 2006

Related U.S. Application Data
(60) Provisional application No. 60/597,409, filed on Nov. 29, 2005.

(51) Int. Cl. H01L 31/0312; H01L 29/76

(52) U.S. Cl. 257/77; 257/401; 257/E25.024

(57) ABSTRACT

A first type of merged power MESFET device includes two monolithically integrated MESFETS. The MESFETS share common sources and gates, and are sized so that one MESFET may be used as a power device while the other is used as a current-sense device. A second type of merged power MESFET device includes two monolithically integrated MESFETS. The MESFETS share a common region which serves as the source for one MESFET and the drain for the second MESFET. This allows the two MESFETS to function as the high and low-side switches for a buck or boost regulator. A third type of merged power MESFET device combines the high and low-side switches with a current-sensing device.

### RELATED APPLICATIONS

This application is one of a group of concurrently filed applications that include related subject matter. The six titles in the group are: 1) High Frequency Power MESFET Gate Drive Circuits, 2) High-Frequency Power MESFET Boost Switching Power Supply, 3) Rugged MESFET for Power Applications, 4) Merged and Isolated Power MESFET Devices, 5) High-Frequency Power MESFET Buck Switching Power Supply, and 6) Power MESFET Rectifier. Each of these documents incorporates all of the others by reference.

### BACKGROUND OF INVENTION

DC-to-DC conversion and voltage regulation is an important function in virtually all electronic devices today. In low voltage applications, especially thirty volts and less, most switching regulators today use insulated-gate power transistors known as power MOSFETs. Power MOSFETs, despite certain high-frequency efficiency and performance limitations, have become ubiquitous in handheld electronics power by Lilon batteries (i.e. operating a 3V and higher voltages). In applications powered by single-cell NiMH and alkaline batteries must operate with as little as 0.9V of battery voltage, however, these limitations are more severe. With such low voltage conditions, power MOSFETs exhibit inefficient and unreliable operation, lacking the gate drive necessary to switch between their low-leakage “off” state and a low-resistance “on” state. With manufacturing variations in their threshold voltage, the voltage the device turns-on, their resistance, current capability, and leakage characteristics render them virtually useless at such low-voltages.

While the silicon power MOSFET has been successful in implementing switching converters up to 2 MHz, their operation above that frequency is too inefficient to be commercially practical. Unfortunately, a much higher switching frequency is needed to eliminate the need for an inductor, now the physically largest component in a power supply.

MOSFET Limitations in Switching Converters

The problem with operating a power MOSFET at low gate voltages is that the transistor is highly resistive and loses energy to self heating as given by I²·R_{DS}·ton where ton is the time the transistor is conducting, I is its drain current and R_{DS} is its on-state drain-to-source resistance, or “on-resistance”. Specifically, a MOSFET's on-resistance is an inverse function of (V_{GS}−Vt), where (V_{GS}−Vt) describes how much the transistor's gate voltage V_{GS} exceeds its threshold voltage Vt. To avoid too much off-state leakage current over temperature, a MOSFET's threshold voltage is practically limited to around one-half volt minimum. At 0.9V gate bias, that means the transistor has only 0.4V voltage overdrive above its threshold, inadequate to fully enhance the transistor's conduction.

Even in lithium ion battery powered applications, power MOSFETs suffer from a number of limitations, especially those adversely impacting their efficiency in high frequency switching applications above 2 MHz. At low voltages, i.e. under 30V, a power MOSFETs high input capacitance becomes a significant and even dominant component of power loss in a switching converter. Input capacitance of a power MOSFET, measured in units of nano-Farads (or nF), comprises a combination of gate-to-source capacitance, gate-to-channel capacitance, and gate-to-drain capacitance, all of which depend on voltage. In power applications, power losses due to the charging and discharging of input capacitance are typically determined as a function of electrical charge rather than capacitance. By summing, i.e. integrating over time, the input current flowing during a switching transition,, the total power needed to drive the MOSFET's gate can more readily be determined. This integral of current over time is a measure of charge, referred to as “gate charge” denoted mathematically as Q_{G} and represents the total charge needed to charge the device's input capacitance to a specific voltage. Because of the large gate width, the gate charge of a power MOSFET can be substantial, typically in the range of tens of nano-Coulombs (i.e. nC). The corresponding “switching” loss driving the device on and off with a gate bias V_{GS} at a frequency f, given by Q_{G}·V_{GS}·f, can at megahertz frequencies be comparable to conduction losses arising from device resistance.

Even more problematic, there is an intrinsic tradeoff between conduction and switching losses in a power MOSFET used in DC-to-DC power switching converters. Assuming fixed frequency operation with variable on-time given by duty factor D, the power loss in the MOSFET can in low-voltage applications be approximated by the equation
P_{LOSS}≈I²·R_{DS}·D+Q_{G}·V_{GS}·f

Increasing the transistor's gate bias to reduce on resistance adversely impacts gate drive switching losses. Conversely reducing gate drive improves drive losses but increases resistance and conduction losses. Even attempts to optimize or improve a power MOSFET's design, layout, and fabrication involve compromises. For example, the gain of the transistor can be increased and its on-resistance for a given size device decreased by using a thinner gate oxide, but the input capacitance and gate charge Q_{G} will also increase in proportion. The tradeoff between on-resistance and gate drive losses limits the maximum efficiency of a converter, becoming increasingly severe at lower operating voltages. For example, the aforementioned tradeoff prevents Lilon-powered switching converters from operating at frequencies over a few megahertz, not because they can't operate, but because their efficiency becomes too low. In one-cell NiMH applications at 0.9V, the devices may not switch at all.

Adapting MESFETs for Power Switching Converters

As an alternative to the power MOSFET, one device that may hold promise for such 0.9V-switching applications is the MESFET, or metal-epitaxial-semiconductor field effect transistor as shown in FIG. 1. Unlike the MOSFET which has an insulated gate, and conducts current by electrically inverting the surface to form a conductive N- or P-channel, the MESFET employs a Schottky rectifier as a gate, modulating the depletion region of the Schottky to control the drain current, preferably without forward biasing or avalanching the Schottky diode during operation. A transition from minimum drain current to maximum drain current can occur in less than one volt change in gate bias, far less than the voltage needed to operate the MOSFET for low-resistance power applications. Its ability to operate at low gate-drive voltages makes the MESFET potentially attractive as a power device, but also introduces certain yet unresolved challenges. Of these challenges, the most significant problem is commercially available MESFETs are limited to the normally-on, or depletion-mode type. Normally-on type switches are unfortunately not useful for power switching applications.

In the example shown the MESFET is made of a wide-band-gap or compound semiconductor such as gallium-arsenide (GaAs), advantageous for its low-leakage Schottky characteristic. Other wide-bandgap or compound semiconductor materials can include indium-phosphide (InP), various II-V compounds, various II-VI compounds, silicon carbide (SiC), or semiconducting diamond. As an alternative to wide bandgap materials, silicon may be used, but silicon's Schottky leakage characteristic is generally not attractive for power applications, especially when operation over temperature and self-heating are considered. Moreover, many wide-bandgap and compound semiconductor materials are better suited for high frequency operation due to their high carrier mobility and high carrier saturation velocities—material properties that improves the aforementioned resistance—gate charge tradeoff.

Frequently the active MESFET device is formed in a deposited epitaxial layer that has different resistivity than the substrate on which it is deposited. In other instances the epitaxial layer may comprise a completely different material and crystalline structure than the substrate.

FIG. 1 illustrates a three-dimensional perspective of a prior art GaAs MESFET comprising epitaxially grown GaAs mesa 12 formed on semi-insulating (SI—GaAs) substrate wafer 11. While theoretically mesa 12 could be made in either P-type or N-type material, in practice only N-type material is convenient for manufacturing and is commercially available while P-type material is not. Most of mesa 12 comprises lightly-doped to moderately-doped material N-GaAs layer 13 except for the top layer which is epitaxially grown as heavily doped N+ layer 14.

A trench 16 is etched into mesa 12 to a depth greater than N+ layer 14. This trench bisects the mesa into two regions, one mesa portion comprising the MESFET's source, the other comprising its drain. Metal 15 formed in trench 16 forms the MESFET's Schottky gate. A second type of metal used for contacting the N+ regions 14 and for contacting the Schottky metal 15 is not shown in this drawing. Mesa 12 is formed by masking and etching the GaAs epitaxial layer 13 and 14 which otherwise would cover substrate 11 in its entirety.

The device is fabricated in a GaAs mesa formed by etching away the GaAs epitaxial layer surrounding it by a chemical or plasma mesa etch. The mesa etch is required to isolate the device from other devices since GaAs and other III-V or binary-element crystals do not readily form insulating dielectrics through thermal oxidation. In some crystals, high temperature processing like thermal oxidation also causes dopant segregation, redistribution, and even stoichiometric changes in the crystal itself. The mesa etch is expensive both in its processing time needed to remove micron thick semiconductor layers, and in reducing useful active wafer area.

In silicon processes a shallow N+ layer is normally introduced through ion implantation or high-temperature “predeposition”, but in some materials the only way to achieve high dopant concentrations is through epitaxial growth. In GaAs MESFET fabrication, this task is achieved by epitaxially depositing N-type layer GaAs 13 followed by deposition of N+ layer 14, generally all performed in the same epitaxy chamber.

At the onset of the epitaxial deposition process the GaAs doping may comprise alternating layers of varying stoichiometry to form a sandwich structure of varying work functions, concentrations, or of P-N junctions. The sandwich structure impedes carrier transport across the sandwich layer, to minimize leakage through the substrate, especially when the substrate is only semi-insulating. In some instances the interfacial buffer layer may also provide stress relief if the deposited epitaxial layer has a different crystalline structure than the substrate (e.g., for silicon on sapphire deposition). Stress relief is especially important in cases where the epitaxial layer has a different crystal lattice and atomic periodicity or a significantly different temperature coefficient of expansion than the silicon substrate.

To those skilled in the art it will be understood that the forgoing discussion illustrating a GaAs MESFET fabricated using a GaAs epitaxial layer deposited atop of GaAs substrate may be adjusted to employ other semiconductor epitaxial materials and alternative substrate materials. Furthermore for the sake of simplicity the presence of interfacial layers at the epitaxy-substrate interface are intentionally not shown except in specific examples discussing their properties.

FIG. 2 illustrates a prior art GaAs MESFET of FIG. 1 in greater detail. In side view, FIG. 2A illustrates cross section 20 illustrating trench 16 covered by Schottky metal 15 etched into mesa 12 through N+ layer 14 and into N− GaAs layer 13. Metal contacts 17, 18, and 19 are used to contact the source, gate, and drain respectively. Plan view 30 illustrates the edges defining the mesa 12, the Schottky metal 15, and the trench 16. The channel length of the device is defined by the trench 16 opening.

FIG. 3 illustrates the steps in fabrication of prior art MESFET device 40. In FIG. 3A, epitaxial layers 43 and 44 are sequentially deposited via epitaxy atop semi-insulating GaAs wafer 41. In typical devices, N− GaAs layer is lightly or moderately doped with doping concentrations ranging from 1E14 cm⁻³ to 4E17 cm⁻³ with a thickness of 1 to 3 micrometers. N+ layer 44 is heavily doped concentrations ranging from 7E14 cm⁻³ to 1E20 cm⁻³ with a thickness of 0.5 to 1 micrometers. Transition layer 42 is formed by varying the epitaxial deposition conditions to minimize mechanical stress between the epitaxial layer and the substrate.

In FIG. 3B, trench 45 is photolithographically defined and etched to a depth greater than N+ layer 44, typically 1 to 2 micrometers. In prior art devices, the vertical depth of trench 45 comprises a small fraction of the total thickness of epitaxial layer 43. The control of the trench depth impacts the transconductance, resistance, and threshold voltage of the device. For the sake of clarity, transition layer 42 is not shown in this or the subsequent drawings.

In FIG. 3C, a Schottky barrier metal is deposited, photolithographically patterned, and etched to form gate metal 46. Photolithographic patterning of the MESFET's Schottky gate may be performed using direct etching or lift-off etching techniques. In direct etching the Schottky barrier gate material to be patterned is first deposited onto the wafer, then the wafer is coated with photoresist (a light sensitive organic emulsion), patterned through a photomask, and the exposed areas of the Schottky gate metal material (not covered by photoresist) is subsequently removed by wet chemical or plasma (dry) etching. In lift-off etching, photoresist is first coated on the wafer and photo-masked to produce exposed semiconductor areas and those protected by un-removed photoresist. The Schottky gate metal is then deposited (at low temperatures by sputtering or evaporation). After gate metal deposition, the photoresist is removed lifting off the metal sitting atop it, leaving the MESFET's gate metal intact. Regardless which method is employed the resulting cross section remains the same, as shown in FIG. 3C.

In FIG. 3D, a layer of interconnect metallization 47, typically gold, is deposited, then in FIG. 3E, the gold layer metal layer is patterned and etched using direct etch methods to form gate electrode 48G, source electrode 48S, and drain electrode 48D. Alternatively, photolithographic patterning of the MESFET's interconnect metal may be performed using the aforementioned lift-off etching techniques.

Finally in FIG. 3F the entire device is isolated by photolithographic masking and etching to form an isolated mesa. Because the device utilizes only a single metallization layer for interconnection, the geometric layout of the device remains limited compared to devices used in silicon integrated circuits. For the sake of clarity, transition layer 42 is not shown in this or the subsequent drawings.

FIG. 4 illustrates the influence of the process design parameters of the electrical behavior of the MESFET. In FIG. 4A, device 50 comprises substrate 51, N− epitaxial layer 52, N+ epitaxial layer 53, trench 54 and gate metal 55. The total epitaxial layer thickness Xₑₚᵢ comprises the thickness of both layers 52 and 53. The trench 54 has a depth xₜ with a resulting thickness for the conducting channel x_{ch} where
x_{ch}=xₑₚᵢ−xₜ

and where the channel thickness x_{ch} affects the device's on-state current and resistance, its threshold voltage, and its off state leakage current.

For conventional prior-art GaAs MESFETs, trench gate 54 is only slightly deeper than the N+ layer. In such a construction, the zero-bias depletion region resulting from the junction barrier between Schottky gate metal 55 and N-GaAs layer 52 is insufficient to reach through layer 52 to semi-insulating substrate 51. The resulting device is referred to as a “depletion mode” transistor since it is in a conductive state even when its gate is shorted to its source, i.e. when V_{GS}=0, as shown by curve 60 labeled I_{DSS} in FIG. 4B. The term depletion mode, often used to describe normally-on MOSFETs, actually is borrowed from the vernacular of junction field effect transistors (JFETs), which behave as normally “on” devices, and whose conductivity is varied through the modulation of the gate P-N junction's depletion region. In this regard MESFETs operate very similarly to JFETs, as a normally-on type device, where drain-to-source conductivity is modulated by varying the width of the reversed biased depletion region of the gate.

Operation of a MESFET may therefore comprise reverse biasing of the MESFET gate to increase the gate depletion region width so as to pinch-off the channel and decrease drain current; or alternatively by forward biasing the MESFET gate to decrease the gate depletion width, allowing more current to flow. Ideally gate current should remain low or near zero, meaning the gate should not be forward biased to a voltage where diode conduction ensues, nor should the gate be reversed biased to such a large potential that significant impact ionization or avalanche breakdown results. So unlike a MOSFET which utilizes an insulated gate input that prevents gate conduction over a wide range of positive and negative gate potentials, the MESFET's Schottky gate is limited to a more narrow operating voltage range.

The impact of changing a MESFET's gate potential on its drain current is illustrated in FIG. 4B for both forward biased (V_{GS}>0) and reverse biased (V_{GS}<0) gate potentials.

By forward biasing the Schottky gate to the maximum positive voltage without conducting substantial gate conduction current, i.e. for V_{GS} around 0.5 to 0.6 volts, the minimum possible on-resistance and maximum device current for the MESFET is illustrated in curve 61. Curve 62 illustrates the condition when the MESFET's Schottky gate is reverse-biased with respect to N-GaAs layer 52. Under reverse bias conditions, the gate depletion region reaches deeper into the epitaxial layer reducing the cross sectional area conducting channel current, reducing the current and increasing on-resistance. In the case where the gate voltage is set to the maximum reverse biased potential before the onset of avalanche of the gate Schottky diode, this minimum drain current condition is herein referred to as I_{Dmin}.

Depending on the doping of the epitaxial layer 52, the gate metal used, and the net epitaxial thickness x_{ch}, the depletion region may not reach through the epitaxial layer even under reverse gate bias. If so, the minimum current in the device I_{Dmin} is not zero (as depicted in the example FIG. 4B). Alternatively, trench 54 may be etched slightly deeper, where reverse bias of gate 55 may fully deplete the epitaxial layer under the trench gate, but only with a reverse biased gate drive. In prior art devices as shown, the zero-biased gate condition (i.e. when V_{GS}=0) results in a current I_{DSS} well above zero, so MESFET comprises a depletion mode device

In the event trench 54 is etched slightly deeper such that the reverse bias of gate 55 fully depletes the epitaxial layer under the trench gate, the magnitude of I_{Dmin} is reduced but because I_{DSS} is not “zero”, the device remains a depletion mode device, not suitable for use as a power switch.

Accordingly, prior art MESFETs have almost exclusively been used only for radio frequency (RF) applications like an RF switch used to multiplex an antenna in a cell phone between its transmitter and receiver circuitry. Used as an RF switch, minimizing a MESFET's “small signal’ AC capacitance is more important than improving its on resistance or saturation current. Since RF circuits generally comprise small-signal non-power applications, depletion mode MESFET devices are commonly available radio frequency components today. Because enhancement mode device characteristics are not required in RF applications, no commercial impetus existed to address the various technical issues prohibiting the manufacture of reliable normally-off MESFETs. As a result enhancement-mode MESFETs were never commercialized.

So the need for an enhancement-mode MESFET with low I_{GSS} (off-state) leakage is mandatory for adapting a MESFET for power switch applications. As a comparison to the prior-art depletion mode MESFET characteristics shown in FIG. 4B, FIG. 4C illustrates the hypothetical characteristics of an enhancement mode MESFET. Specifically curve 65 illustrates the transistor's drain current at a zero-volt gate bias should be very low, having an I_{DSS} value near zero (e.g. under 1 μA). Curve 67 illustrates the drain leakage may be further depressed, but only slightly, by the application of reverse-biased gate bias. Curve 66 illustrates the enhanced conduction of the MESFET under a condition of positive gate bias. When the gate potential is biased to the maximum positive potential before the onset on forward biased conduction current in the Schottky gate, the MESFET's drain current reaches its maximum value I_{Dmax}, and its minimum on-resistance R_{DSmin}.

FIG. 4D illustrates the conduction characteristics of the gate Schottky diode. The maximum forward bias of Schottky gate 55 is determined by its onset of conduction, typically at 0.5V to 0.7V. To minimize DC drive losses, the gate should be forward biased ideally with less than one milliamp of gate conduction current, and ideally with gate currents in the microampere range. Furthermore, the maximum reverse bias of Schottky gate 55 is determined by its avalanche breakdown to N+ layer 53. The gate should not be driven into avalanche or device damage may result. So unlike a MOSFET's wide positive and negative gate voltage capability, the MESFET is limited to a voltage Vf in the forward biased direction and to a breakdown voltage BV_{GD} in its reverse direction.

FIG. 4E illustrates the impact of the net epitaxial thickness x_{ch} under the gate. As shown by curve 70 for V_{GS}=0, thicker dimensions mean that the epitaxial layer cannot be pinched off at zero volts. Such normally-on devices and are by definition depletion mode. Any epitaxial channel thinner than some critical value (see dashed line 73) represents a device that is shut off at a zero gate bias condition and is by definition enhancement mode. Curve 71 illustrates an increase in conduction current increase resulting from slightly forward biasing the gate. In contrast, curve 72 illustrates a decrease in drain current from reverse biasing of the gate, where devices with epi thicknesses above some critical thickness (see vertical dashed line 74) cannot be shut off even with reverse bias. In every bias condition, thinner channels conduct less current than thicker ones.

FIG. 4F illustrates three different MESFETs' drain currents as a function of positive and negative gate bias. In enhancement mode device A, curve 75 illustrates a near zero off state leakage I_{DSSA} and a maximum current limited by the maximum positive gate voltage before the onset of Schottky conduction (illustrated by line 78). Such a device has the electrical characteristics of a normally off switch, useful in power applications. In device B typical of the prior art, the device is conducting for V_{GS}=0, i.e. I_{DSSB}>0, but can be shut off by applying a reverse bias to its gate. Such devices, while not generally useful for power switch applications, are commonly used for RF switches in cell phones. Device C (illustrated by line 77) is a device with the thickest epitaxial layer and cannot be shutoff even if the maximum negative bias shown by dashed line 79 is applied. While such device may still be used in small-signal circuit applications (such as an amplifier or gain element), they are not useful as a power switch since they cannot be shut off, even with a high negative gate bias.

FIG. 5A illustrates the bias conditions needed to turn off MESFET switch 80, including a gate to source short, i.e., where V_{GS}=0, and where depletion region 81 pinches off epitaxial layer 83. The highest electrical field point 82 occurs at the edge of the trench where the gate and the drain meet, at the Schottky gate edge (point 84), or otherwise along the surface in between these two points. As shown in FIG. 5B, the onset of avalanche at a higher drain voltage leads to a rapid rise in current. The combination of high electric fields and high current densities in the vicinity of point 82 leads to localized carrier generation, avalanche, and hot carriers that can destroy the device. The MESFET in its prior art form is therefore not suitable for power switching applications because of its inability to survive even temporary over-voltage conditions.

Aside from certain fundamental frailties intrinsic to the device's present construction, commercially available MESFETs have other design limitations that further degrade their avalanche ruggedness. In prior art device 90 shown in FIG. 6A, Schottky gate 93, trench 92, and gate metal 94G, divide and separate drain 94D (and drain pad opening 98D) from source 94S (with corresponding pad opening 98S). The serpentine gate (biased via pad opening 98G) terminates at two edges of the etched mesa defined by photomask and mesa etch layer 91. Since the gate extends to the edges of the mesa, the electric field at the drain-to-gate interface is especially high along the surface at points A and B as shown. Due to surface state charges, the origin of leakage current and the onset of avalanche will be most severe at the device surfaces, especially at the mesa edge at points A and B.

These locations will be especially fragile to any electrical abuse, as illustrated in the three-dimensional illustration of device 99 in FIG. 6B, where trench 92 and gate metal 93 exhibit a high electric field along the etch mesa surface of the device, especially at point A at the mesa surface.

Even if a suitable power device is available to meet requisite ruggedness, capacitance, and speed requirements of high frequency DC-to-DC converters, other challenges exist, especially those relating to device-circuit interactions and tradeoffs. In the prior art, for example, other challenges to implementing high frequency DC-to-DC converters involve fast shoot-through protection, sensing switch current, and minimizing stray inductance of the converter components. Ideally these issues should be addressed using methods having minimum sensitivity to process variations and without adversely affecting converter efficiency.

Converter Frequency Limitations of Break-Before-Make Circuitry

In FIG. 7A, synchronous Buck converter circuit 100 comprises high-side MOSFET switch 101 (with intrinsic anti-parallel diode 102), inductor 103, output capacitor 104, Schottky diode 105, low-side MOSFET synchronous rectifier 106 (with intrinsic diode 107), pulse width modulation (PWM) controller 108, and shoot-though protected gate driver 109.

Shoot-through protection, also known as “break-before-make” circuitry (with the acronym BBM) is necessary to prevent simultaneous conduction in synchronous converter transistors such as those comprising switch 101 and in synchronous rectifier 106 in circuit 100. In the event that these two devices exhibit overlapping periods of conduction, a momentary short circuit condition will exist. Crow-barring the battery input, i.e. shorting the battery terminals even for a moment, drains the battery of precious stored energy, and in some instances may result in potentially dangerous spikes in current, overheating, or even a fire hazard. The purpose of the BBM circuitry is to insure one transistor is fully off before the other one is allowed to turn on. While the BBM interval (where both transistors are off) must be sufficiently long in duration to guarantee the shoot through condition never occurs, extremely long duration BBM intervals lead to increased power losses since the current flowing through inductor 103 must be carried by diode conduction in either Schottky 105 or by the P-N diode 107 intrinsic to MOSFET 106. Since a forward biased diode has a larger voltage drop than MOSFET 106 has in its “on” condition, the power loss is higher during the BBM interval.

Unfortunately at increasing frequencies, break before make circuit 109 becomes increasingly problematic for circuit implementations where the threshold voltages of the P-channel and N-channel transistors in the BBM buffer circuitry are not correlated to (i.e. do not “track”) the threshold of N-channel and P-channel power transistors 101 and 106.

With varying threshold voltages, the break-before-make time will vary, in some cases increasing the BBM duration, and in other cases shortening it. Even ignoring switching losses and poor efficiency, the variability of the BBM interval therefore sets a limitation in the maximum frequency of a converter.

If the BBM circuit and the power MOSFETs are implemented monolithically in silicon and the circuit is designed to cancel threshold variations the MOSFETs, the frequency limitation imposed by BBM considerations is approximately 5 MHz. If the power MOSFETs comprise discrete lateral low voltage devices not correlated to the BBM buffer, accounting for process variability practically limits BBM and converter operation to 2 MHz. Moreover, lateral integrated silicon power MOSFETs suffer from an intrinsically poor tradeoff between on-resistance and gate charge. This tradeoff limits their use to converter switching rates of a few megahertz, frequencies too low to eliminate the need for large inductors in switch-mode power supplies.

Another alternative is to implement the power MOSFETs as vertical discrete devices such as trench power DMOSFETs or vertical planar DMOSFETs. In such cases, acceptable operation even at 1 MHz can be challenging since discrete devices do not necessarily share the same wafer during production, exhibit statistically uncorrelated threshold voltages, and have high gate-charge for a given on-resistance.

Similarly adapting other semiconductor devices such as discrete MESFETs face similar challenges since MESFET characteristics do not track accurately from lot to lot.

In summary, whenever BBM circuitry cannot be constructed using the same process as the power stage, prior art switching converter methods do not predictably operate at high frequencies and short BBM intervals. The problem is further exacerbated since vertical power devices themselves have uncorrelated threshold voltages, i.e. are not co-fabricated on the same wafer.

The substitution of discrete power MOSFET with power MESFETs faces the same issues, namely that the devices cannot be monolithically integrated without isolation and that their threshold voltages will therefore not track one another.

Converter Frequency Limitations of Current Sense Circuitry

Current sensing in DC-to-DC converters further complicates high frequency operation. Again referring to prior art circuit 100 in FIG. 7A, resistor 116 is used to monitor the current in MOSFET 106, and indirectly to monitor the current in inductor 103. In this example, the voltage signal is amplified by operational amplifier 110 and then used either to affect the PWM control 108 or to detect a short circuit condition with circuit 111, or both.

In the case of short circuit detection, the function is essentially one of monitoring the voltage drop on resistor 116 for some maximum voltage condition. Should that condition occur, then too much current is flowing and converter 100 can be shut down. In other converters, control schemes such as current mode use the current information to dynamically adjust the slope of the ramp generator in PWM control circuit 108, affecting the converter's stability and transient response characteristics. In either event the resistance R of resistor 116 must be sufficiently large to generate a measurable voltage, typically of at least 20 mV. For example to measure 0.5A, resistance R would need to be at least 40 mΩ. If power MOSFET 106 has a resistance of 100 mΩ, the inclusion of current sense resistor 116 represents a 40% increase in resistance and conduction loss in the synchronous rectifier function of the converter.

The adverse impact of resistor 116 on conduction loss can be mitigated by increasing the size of MOSFET 106 to reduce its resistance to 60 mΩ, so that the sum of the resistances of the MOSFET and the sense resistance stays constant at 100 mΩ, but at the expense of a bigger power device. Unfortunately, even ignoring the expense of such an approach, the 40% larger MOSFET also exhibits a 40% increase in its gate capacitance and gate charge, i.e. 1.4 times the Q_{G} of the original device. The gate drive loss of MOSFET 106 is therefore increased in proportion, forcing a compromise between switching losses and gate drive losses.

In regards to the impact resistor 116 has on converter efficiency, whether the resistor is placed in series with the source of N-channel MOSFET 106, or placed electrically in series with the source of P-channel MOSFET 101, or placed in series with inductor 103 is irrelevant. Any increased resistance in the main power path can only be reduced by sacrificing gate drive efficiency.

FIG. 7B illustrates the use of a current mirror approach to monitor the MOSFET's current indirectly through a small sense device. In circuit 120, P-channel power MOSFET 121 having a gate width nW₁ is integrated onto the same die as small sense device 122 having gate width W₁, n-times smaller than the large device. In the linear region, the resistance of sense device 122 is therefore n-times larger that of power device 121. The drain current flows through a bias network comprising resistor 133 and N-channel MOSFET 129, part of a current mirror formed with N-channel 130. So long as the value R of resistor 133 is chosen sufficiently large to maintain V_{y}≈Vₓ, then MOSFET 122 will operate in its linear region and the current in power MOSFET 121 can be estimated since devices 121 and 122 have the same threshold and the same gate drive voltage.

Unfortunately, this and similar current sense methods are only useful if the main and sense MOSFETs are manufactured in a process capable of integrating multiple isolated device—a feature not always available in power transistor fabrication. Vertical power-MOSFETs fabricated on the same wafer, for instance, share a common drain (rather than a common source) and cannot be used to produce a separated drain current sense circuit like circuit 120.

Similarly MESFET processes are not designed to produce isolated integrated devices. The integration of current sensing into a MESFET has previously not been required since MESFETs were only used in radio frequency applications. Furthermore, since many III-V and II-VI compound semiconductor materials such as gallium-arsenide cannot be oxidized or do not form high quality dielectrics; device-isolation requires expensive mesa etch processes. Large step heights resulting from the mesa etch also make the process of on-chip metal interconnection difficult or impossible due to the resulting non-planar surface.

Converter Frequency Limitations of Stray Inductance

Another consideration in high-frequency DC-to-DC converter design is the presence of stray and parasitic inductances. Stray inductance occurs in any conductor of substantial length, such as a bond wire, a printed circuit board trace, the leads of a semiconductor package, etc. How much inductance is too much inductance depends on the frequency the power converter operates. While at 200 kHz, only large bulk inductors and transformers must be considered in power applications, above several megahertz, even a bond wire is significant.

Referring again to FIG. 7A, circuit 100 illustrates several inductors, namely the component inductor 103 and stray inductances 12, 113, 114 and 115. These stray inductances arise from the bond wires, package leads, and printed circuit board traces connecting these components. The less these components are integrated, the greater the dimensions and the larger the magnitude of stray inductances will be. For example inductor 114 is associated with the drain connection of N-channel power MOSFET 106, inductor 113 is associated with the drain connection of P-channel power MOSFET 101, inductor 115 is associated with the package of Schottky diode 105, and inductance 112 is associated with the printed circuit board trace connecting to component inductor 103.

Not all inductances have equally adverse effects on converter operation. For example, stray inductances 113 and 114 are in series with power MOSFETs 101 and 106 and impede their ability to make rapid changes without being subjected to noise and voltage spikes resulting from inductor reactance, namely, V_{L}=L(dl/dt). The noise generated by stray inductor 114 subjects MOSFET 106 to drain voltage spikes that potentially can be greater than the input voltage Vᵢₙ. Similarly inductor 113 subjects MOSFET 101 to increased drain voltage stresses and potentially could drive the device into avalanche. If source inductance (not shown) is also present, the varying source potential can make it difficult to rapidly turn off a conducting device, and thereby contribute to unwanted power loss, lower efficiency, and an overall increase in converter power dissipation.

In contrast to source and drain inductance, inductor 112 is in series with a much larger inductor 103, and since L₁>>L₂, parasitic inductance 112 has no impact on circuit operation whatsoever.

Inductor 115 adversely slows down conduction in Schottky 105. To be beneficial in operation, diode 105 needs to conduct rapidly to clamp the drain voltage and divert the current away from diode 107 during the BBM interval; otherwise stored minority carriers and increased switching losses from P-N diode recovery of diode 107 may result. Some manufactures assemble Schottky 105 and a discrete power MOSFET 106 into the same package to reduce the magnitude L₅ of stray inductance 115.

To eliminate stray inductance it is important to co-package or monolithically integrate both power switches 101 and 106 in a synchronous converter, ideally with Schottky 105 as well. But vertical power MOSFET cannot be monolithically integrated in this manner, nor can present day MESFETs.

So what is needed for improved multi-megahertz DC-to-DC conversion is a fast, low-threshold low-gate-charge normally-off power transistor with robust avalanche characteristics formed in a manner allowing more than one transistor to be integrated and connected into various push-pull and current sense circuit topologies and fabricated using a single semiconductor wafer offering matching thresholds and minimal interdevice parasitic inductance.

### SUMMARY OF INVENTION

MESFET with Integral Current Sensing

One aspect of the present invention provides an N-channel power MESFET with integrated current sensing capability. For a typical embodiment, two N-channel MESFETs are monolithically integrated and share a common source connection S, a common gate connection G, and separate drain connections D1 and D2. The first MESFET has a channel length L and a gate width W. The second MESFET has gate length L identical to the first MESFET and a gate width n·W where n may range from as small as ten to as large as ten million. With its large gate width the second MESFET, a device suitable as a power switch in DC-to-DC converters, exhibits a much lower on resistance than the first MESFET. This allows the first MESFET to be used to monitor the current in the larger device without the need to insert a current-sense resistor in series with second MESFET. By eliminating the need for a current sense resistor, the second MESFET can achieve a low total resistance without having to enlarge the device size and adversely increase its gate charge.

Preferably, the two MESFETs are fabricated using a single “Figure Eight” shaped gate that surrounds the separate drains of the MESFETs. A common source region surrounds the gate. The advantage of this layout lies in its ability to integrate and merge two MESFETs into a circuit for sensing power MESFET current without the need for a series-connected sense resistor and without the use of any device isolation requiring extra processing (such as a trench or mesa etch). The MESFETs, being fabricated simultaneously and monolithically have matched threshold and breakdown characteristics. Since the MESFETs' common source and source metal surround the entire device, the merged device may be separated from other die on the same wafer using sawing and without the need for a mesa etch along the device's periphery.

Merged Power MESFET Pair for Push-Pull Applications

Another aspect of the present invention provides an integrated N-channel power MESFET pair for power conversion circuitry. For a typical embodiment, two N-channel MESFETs are monolithically integrated and share a common output terminal. The drain of the first MESFET and the source of the second MESFET are both connected to the output terminal. In the context of a symmetric MESFET, the term source and drain are arbitrary since the device is symmetric and has no intrinsic source-to-drain PN diode (common to power MOSFETs).

The integrated N-channel power MESFET may be used to provide the high and low-side switches for boost, buck and boost buck converters. Depending on the particular application, the two devices may have similar gate width dimensions, device areas, and on-resistances, or may be sized to maximize efficiency. For example, in a synchronous Buck converter having a large conversion ratio, i.e. where Vout is a small fraction of Vbatt, the low-side MESFET must conduct for longer duration in each switching period, and may be therefore increased in size to reduce its resistance and corresponding conduction loss.

For one possible implementation, a common region surrounds a high-side MESFET and a low-side MESFET. The common region serves as the drain for the low-side MESFET and as the source for the high-side switch. Each MESFET is fabricated as a ring-shaped gate. For the low-side MESFET, the gate surrounds the MESFET's source. For the high-side MESFET, the gate surrounds the MESFET's drain. By merging two MESFETs monolithically, parasitic inductance between the devices is completely eliminated. By eliminating stray inductance, voltage stresses on the power devices is reduced, eliminating the need for over-rating the devices' voltage capabilities. As a result both reliability and efficiency may be improved, in either synchronous buck or synchronous boost topologies.

Merged Power MESFET Pair with Integral Current Sensing

Still another aspect of the present invention adds a current sensing MESFET to the integrated N-channel power MESFET pair just described. The resulting circuit includes a low-side power MESFET, a high-side (or floating) MESFET, and current-sense device. Typically, the low-side switch and sense devices share a common gate while the high-side switch has a separate gate from the low side switch. Monolithically integrated, the MESFET matching and low parasitic inductance makes switching power conversion at multi-MHz frequencies feasible.

For one possible implementation, the low-side switch and high-side switch are arranged side-by-side and surrounded by a common region. The common region functions at the source for the high-side switch and the drain for the low-side switch. The high-side switch is formed as a ring shaped gate that surrounds the MESFET's drain region. The low-side switch is formed as a ring shaped gate that surrounds the MESFET's source region.

The current-sense device is formed within the source region of the low-side switch as a ring shaped gate that surrounds the drain of the current-sense device. Since the current sense-device and the low-side switch share a common gate, the gate of the low-side switch is electrically connected to the gate of the current-sense device. By surrounding the sense MESFET with the source of the low-side power MESFET no isolation is needed to integrate the sense device into the merged power MESFET half-bridge.

### DESCRIPTION OF FIGURES

FIG. 1 Three-dimensional illustration of prior-art conventional GaAs MESFET.

FIG. 2 Illustration of conventional prior-art GaAs MESFET (A) cross section (B) plan view.

FIG. 3 Manufacturing process sequence for prior-art conventional GaAs MESFET (A) epitaxial deposition (B) trench etch (C) Schottky gate deposition (D) metal deposition (E) metal patterning (F) mesa etch.

FIG. 4 Comparison of depletion mode and enhancement mode MESFET devices (A) cross section (B) depletion-mode I_{D} vs. V_{DS} family of curves (C) enhancement-mode I_{D} vs. V_{DS} family of curves (D) MESFET gate characteristics (E) effect of trench depth on threshold (F) drain current of different threshold voltage MESFETs.

FIG. 5 Avalanche breakdown of prior art MESFET (A) cross section illustrating avalanche mechanism (B) I-V avalanche characteristics for depletion and enhancement mode MESFETs.

FIG. 6 Layout of prior art conventional MESFET (A) plan view (B) 3-D projection.

FIG. 7 Example of synchronous Buck converters illustrating parasitic elements affecting high frequency operation (A) resistor current sense circuit (B) current mirror sense circuit.

FIG. 8 N-channel power MESFET with integrated current sense (A) schematic (B) application circuit example (C) plan view of device layout.

FIG. 9 Integrated N-channel power MESFET pair (A) schematic (B) synchronous boost converter application circuit example (C) synchronous Buck converter application circuit example (D) plan view of device layout.

FIG. 10 N-channel power MESFET pair with integrated current sense (A) schematic (B) plan view of device layout (C) cross section of device (D) Buck converter application.

FIG. 11 Triple concentric power MESFETs.

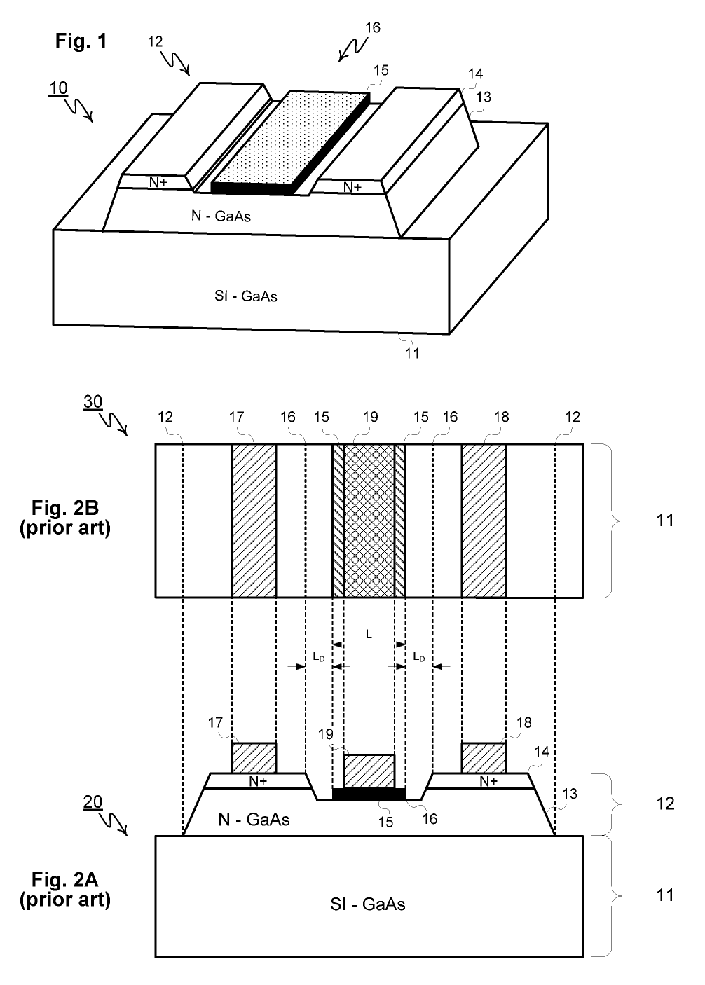

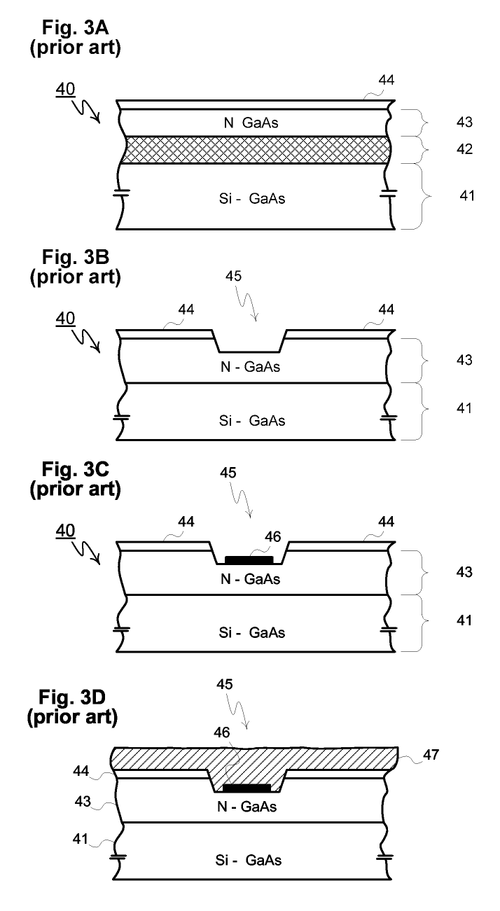

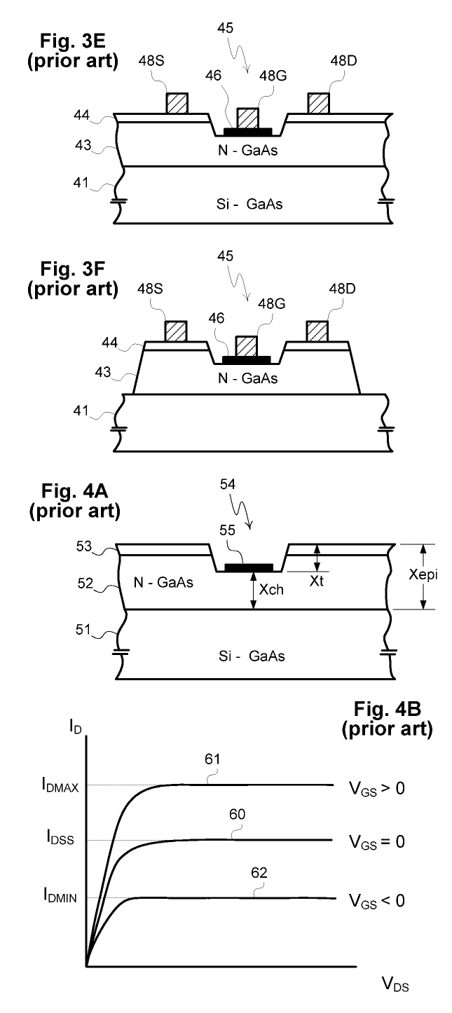

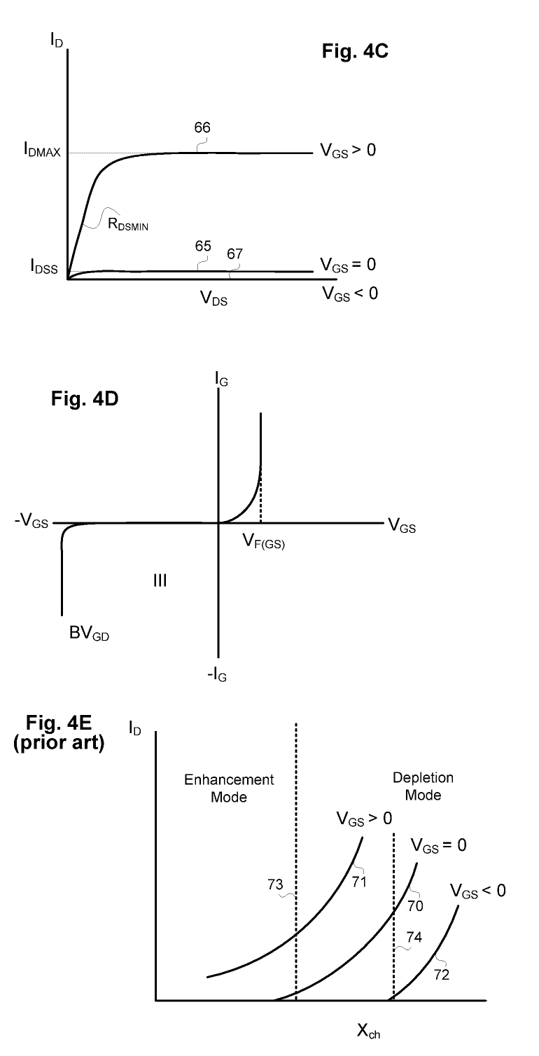

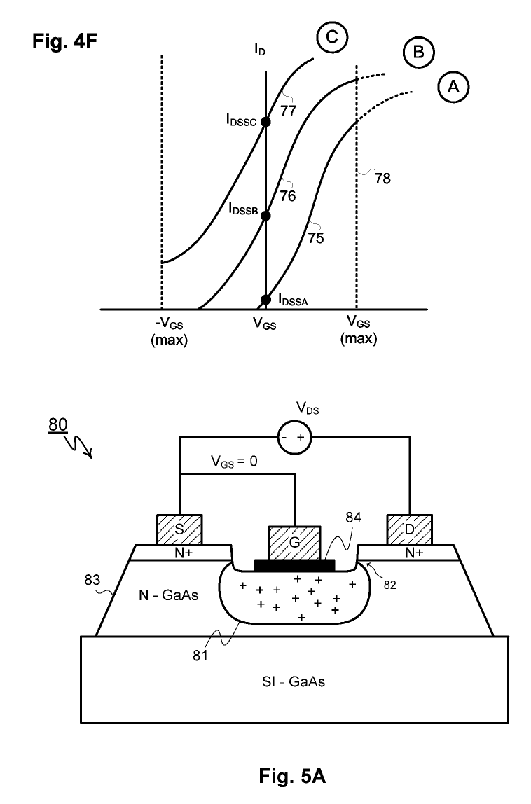

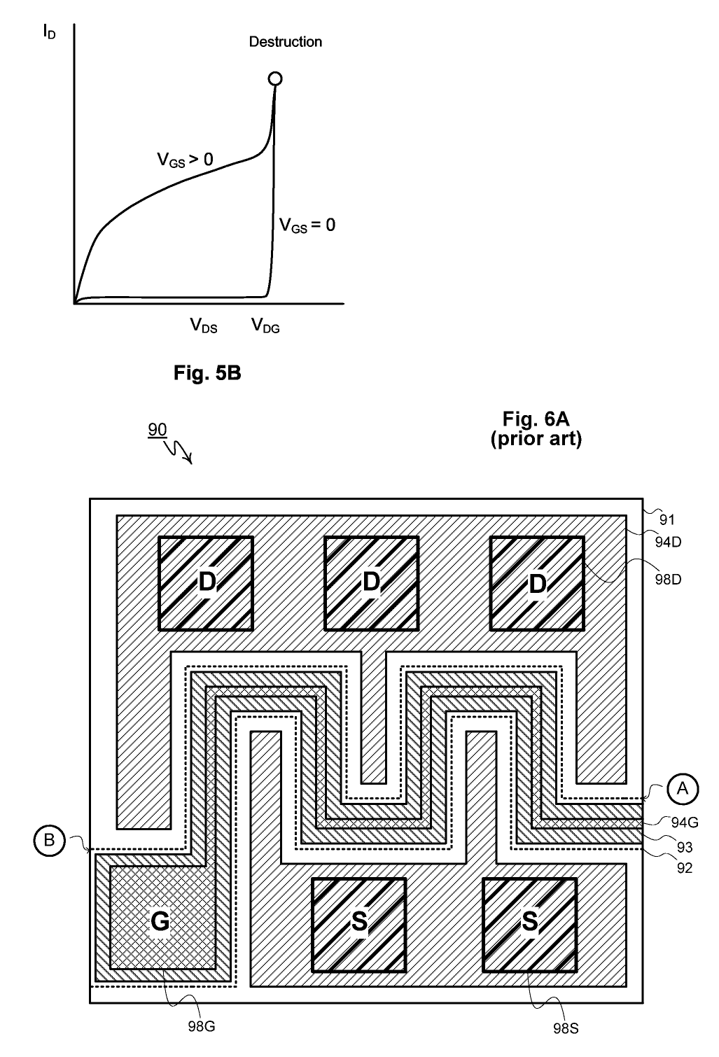

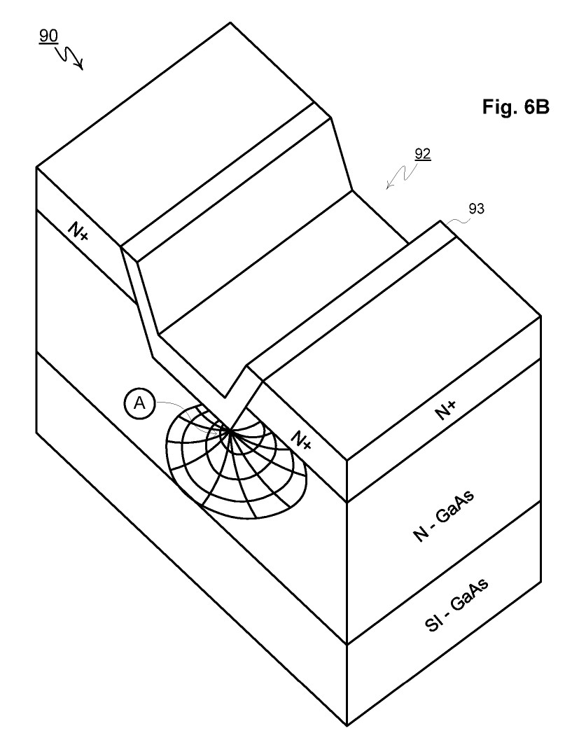

### DESCRIPTION OF INVENTION

Adapting MESFETs for efficient, robust, and reliable operation in switching power supplies requires innovations and inventive matter regarding both their fabrication and their use. These innovations are described in the related applications previously identified. The design and fabrication of power MESFETs for low noise, high frequency operation with minimal parasitics and with fast current monitoring capability, especially for use in switching converters, requires inventive matter, which is the main subject of this invention disclosure.

Specifically, high frequency operation of power MESFETs require a means to sense the current flowing in the device without the need to introduce added resistance or capacitance or to otherwise sacrifice device avalanche ruggedness. Furthermore, in synchronous Buck, synchronous boost, and other converter topologies, push-pull power switches are used in pairs comprising a low-side switch with either a high-side or floating switch. In such cases, the cost effective integration of isolated MESFET pairs having matched threshold voltage characteristics, minimal stray inductance, and device-to-device isolation is critical.

One possible solution for such issues is addressed through the monolithic integration of merged MESFET devices, which is the subject of this invention. Remedies for each of the issues addressed in this disclosure may be applied individually, or in combination.

MESFET with Integral Current Sensing

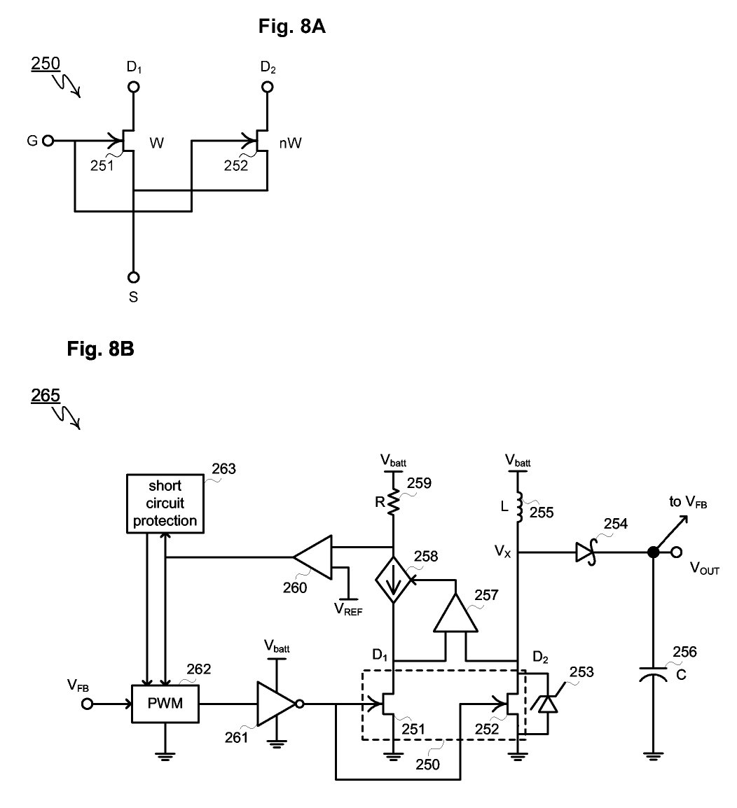

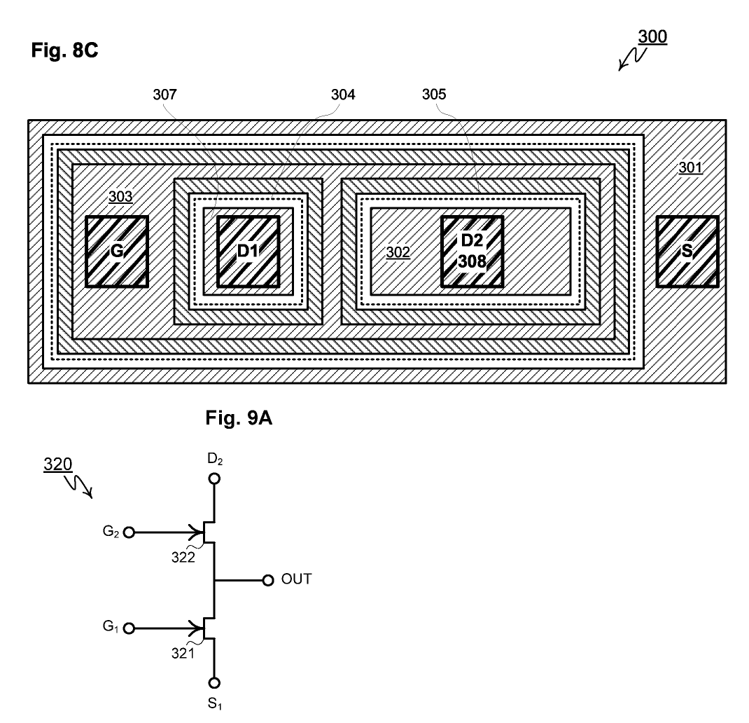

FIG. 8 describes an N-channel power MESFET with integrated current sensing capability. In the schematic of FIG. 8A, circuit 250 comprises two monolithically integrated N-channel MESFET devices 251 and 252 sharing a common source connection S, a common gate connection G, and separate drain connections D1 and D2. MESFET 251 has a channel length L and a gate width W. MESFET 252 has gate length L identical to MESFET 251 and a gate width n·W where n may range from as small as ten to as large as ten million. With its large gate width MESFET 252, a device suitable as a power switch in DC-to-DC converters, exhibits a much lower on resistance than MESFET 251 which may be used to monitor the current in the larger device without the need to insert a current-sense resistor in series with power device 252. By eliminating the need for a current sense resistor, the power MESFET 252 can achieve a low total resistance without having to enlarge the device size and adversely increase its gate charge.

In its linear region of operation current-sensing MESFET 251 has an on-resistance R_{DS1}. Under the same gate bias condition (i.e. with a gate-to-source voltage V_{GS}) MESFET 252 has an on-resistance R_{DS2} having a magnitude proportional to resistance R_{DS1} by the ratio of the devices' gate widths, or as R_{DS2}=(R_{DS1}/n). The voltage drop of the two devices is then given by
V_{DS1}=I_{D1}·R_{DS1}
V_{DS2}=I_{D2}·R_{DS2}

If the two devices have similar drain voltages, i.e. V_{DS1}=V_{DS2}, then

$${I}_{D 1} = {I}_{D 2} [ \frac{{R}_{DS 2}}{{R}_{DS 1}} ] = \frac{{I}_{D 2}}{n}$$

The drain voltage of the sense MESFET may be forced to acquire the same voltage as the main power MESFET using an amplifier, or may be sized to exhibit approximately the same voltage at a specified current using manufacturing statistics of the MESFET's current-voltage characteristics.

An application circuit example of a current sensing circuit 265 using merged current sensing MESFET 250 is illustrated in FIG. 8B. In this boost converter circuit example, power MESFET 252 is controlled by PWM controller 262 and driven by gate buffer 261 to produce an output voltage V_{OUT} greater than the battery input voltage V_{batt}. Step up conversion is accomplished through the switching of current in inductor 255 by power MESFET 252, rectified by Schottky diode 254 and filtered by capacitor 256. Zener diode 253 helps protect power MESFET 252 from potentially damaging overvoltage transients.

Merged current sensing MESFET 250 comprises power MESFET 252 (having a gate width n·W) and current sense MESFET 251 (having a gate width W, n-times smaller than the power device). Working together as a transconductance amplifier, differential-input amplifier 257 drives controlled current-source 258 to a current which forces the voltage at the drain D1 of MESFET 251 to be equal to the voltage at the drain D2 of power MESFET 252. As per the above analysis, under such conditions the current in sense MESFET 251 is 1/n that of the current in the main power MESFET 252. The current in sense MESFET 251 is converted into a voltage signal through resistor 259 and may be used to modify the operation of PWM control circuit 262. For example, in current-mode controlled DC-to-DC converters, the slope of the ramp generator (used as the clock in the PWM control) is adjusted dynamically in proportion to the inductor current, in this case represented by the voltage output of amplifier 260.

Another use for monitoring the power MESFET current is to be able to quickly react to a short-circuited load condition. In the event of the output of converter 265 is shorted to ground, the duty factor of the converter (i.e. the switch on-time per period) jumps to 100% and the current in inductor 255 increases rapidly. To prevent inductor saturation and excessive currents, current protection circuit 263 (typically a comparator) senses the condition and shuts off gate buffer 261 and power MESFET 252, thereby rapidly eliminating any further current increase in inductor 255. While sensing and reacting to the short circuit condition requires analog circuitry such as amplifier 257, current source 258 and amplifier 260, the result is digital, i.e. the power device is switched off.

Layout of a merged power MESFET with integral current sensing is problematic since many III-V compounds such as GaAs lack the ability the ability to be oxidized. As a result, MESFETs are not easily isolated.

FIG. 8C illustrates a plan view of inventive current-sensing MESFET merged device layout 300, a design integrating two power MESFETs monolithically without the need for isolation capability. In the example shown, source metal and source-contact region 301, common to both sense and power devices, entirely surrounds gate interconnect metal 303, Schottky gate metal 305, and trench 304. This structure in turn surrounds drain metal 307 of the sense MESFET (drain D1) and also drain metal 302 of main power MESFET (drain D2), the trench gate having a figure-eight shape. Pad opening 308 is required for the MESFETs common source “S”, common gate “G”, and separate drains “D1” and “D2”. The shape of the drain of power MESFET 252, i.e. drain 302 in device 300, may comprise a square, a rectangle, a multi-finger interdigitated pattern or any other geometric shape so long that the Schottky gate 305 and trench 304 surrounds drain metal 302. As shown the ring-shaped trench feature is smaller than Schottky gate metal 305, i.e. the trench is inside the Schottky metal ring. This layout assumes that a sidewall dielectric prevents Schottky metal 305 from touching the sidewall of trench 304. In the event the device fabrication process does not include this sidewall oxide, Schottky metal 305 must be contained entirely inside trench 304.

In summary, the resulting merged device comprises a “figure 8” shaped gate enclosing two separate drains and sharing a common source exterior.

The advantage of this layout lies in its ability to integrate and merge two MESFETs into a circuit for sensing power MESFET current without the need for a series-connected sense resistor and without the use of any device isolation requiring extra processing (such as a trench or mesa etch). The MESFETs, being fabricated simultaneously and monolithically have matched threshold and breakdown characteristics so that on-resistance and transconductance scale with the gate width multiplier n. Since the MESFETs' common source and source metal 301 surround the entire device, the merged device may be separated from other die on the same wafer using sawing and without the need for a mesa etch along the device's periphery.

The design also saves space, by sharing a common gate and gate pad for both MESFETs instead of requiring separate pads. A dual MESFET layout with separated gates could also be used to implement circuit 250, but in a less area efficient manner, especially since most convenient sense circuits require the two gates are biased to the same potential.

Merged Power MESFET Pair for Push-Pull Applications

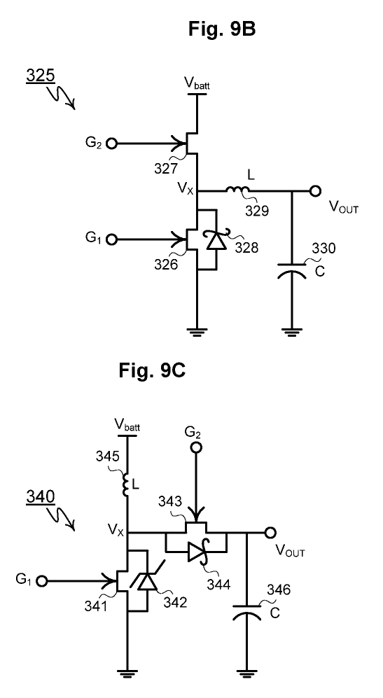

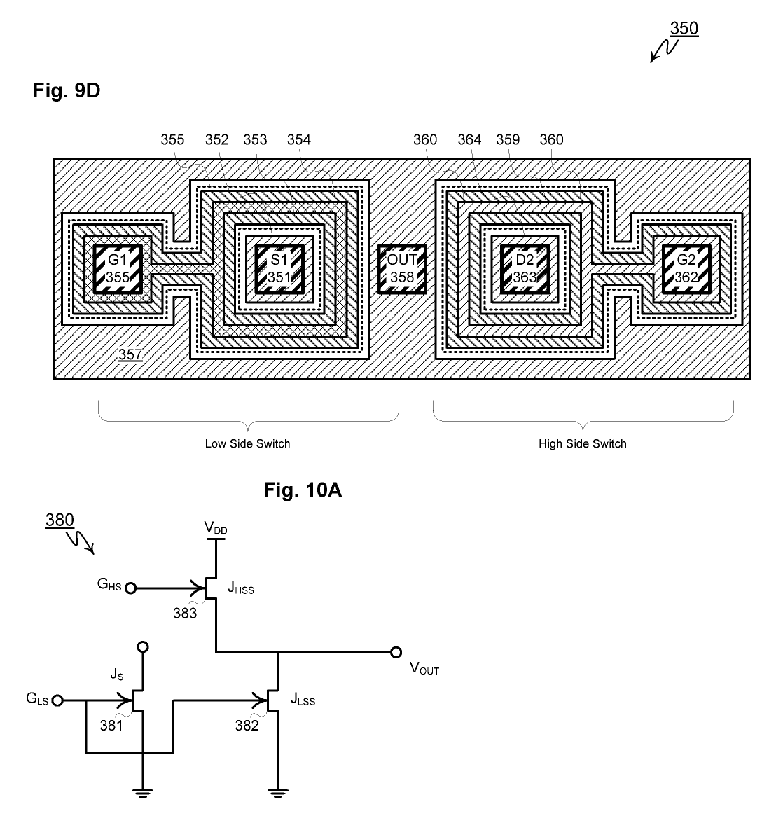

FIG. 9 illustrates an integrated N-channel power MESFET pair and its application in power conversion circuitry. In FIG. 9A, a schematic representation 320 of a merged N-channel MESFET pair illustrates two MESFETs, 321 and 322 sharing a common electrical connection (labeled OUT). MESFET 321 comprises gate G1 with a corresponding source S1 and drain connected to the shared OUT terminal, while MESFET 322, with gate G2 and drain D2 has its source connected to the same shared OUT terminal. In the context of a symmetric MESFET, the term source and drain are arbitrary since the device is symmetric and has no intrinsic source-to-drain PN diode (common to power MOSFETs).

With no intrinsic diode limiting its circuit connection and polarity, numerous device layouts are possible for merged implementations. For example in circuit 325, an N-channel power MESFET pair comprising ground-connected low-side switch 326 and battery-connected high-side switch 327, is connected in a switch topology applicable in a synchronous Buck switching converter. The common node of the merged MESFET pair, labeled Vx, is connected to inductor 329 which in turn is connected to the circuit's output with filter capacitor 330. The common node voltage Vx and the converter's output voltage Vout are determined by the constant high-frequency switching of the two MESFETs, ideally through some form of pulse-width or pulse-frequency modulation control scheme controlling gates G1 and G2. Schottky diode 328 is included to maintain the constant current in inductor 329 during the break-before-make deadtime, when both switches are off.

In synchronous Buck converters, the two MESFET devices may have similar gate width dimensions, device areas, and on-resistances, or may be sized to maximize efficiency. For example, in a synchronous Buck converter having a large conversion ratio, i.e. where Vout is a small fraction of Vbatt, the low-side MESFET must conduct for longer duration in each switching period, and may be therefore increased in size to reduce its resistance and corresponding conduction loss. In general the larger gate width MESFET should constitute which ever device spends more time conducting per cycle. For example if a Buck converter's output is closer to its input voltage, i.e. having a duty cycle greater than 50%, then the high side MESFET should be larger than the low-side rectifier device. For a synchronous Buck converter typically operating with a low output voltage, its low duty cycle (e.g. 20%) means that the low side MESFET will conduct more time than the high side device and should be sized larger accordingly.

The same merged MESFET pair can be adapted for other converter topologies simply by rearranging the connection of the inductor and high-side switch. For example, in synchronous boost converter circuit 340 shown in FIG. 9C, the merged N-channel MESFET pair comprising low-side switch 341 and synchronous rectifier 343 has inductor 345 connected between the input Vbatt and the common node Vx, while synchronous rectifier 343 is connected between Vx and the converter's output. The output is filtered by capacitor 346. Schottky diode 344 is included to maintain the constant current in inductor 345 during the break-before-make deadtime, when both switches are off. Zener diode 342 is added to prevent excessive voltages at Vx from damaging MESFET 341. In synchronous boost applications the size and gate width of low-side switch 341 is typically greater than that of synchronous rectifier 343, since the peak current in a boost converter's switch is necessarily higher than the average output current.

FIG. 9D illustrates one possible plan view of merged MESFET pair 350 including a common node represented by shared metal 357 surrounding two MESFET devices and connected through pad opening 358. One MESFET, labeled as a low-side switch (i.e. with a separate source and a shared drain), comprises source metal 352, source pad opening 351, Schottky gate metal 354, trench gate 355, gate metal 353, and gate pad opening 355. Common metal 357 serves as the drain of the low-side switch. As a low-side device source 352 is grounded in either synchronous-boost or synchronous Buck converter topologies. As in the previous examples, the trench gate ring may be drawn wider than the gate Schottky metal as shown, or alternatively smaller in width provided that a sidewall spacer dielectric is employed on the trench sidewall to prevent Schottky metal 354 from touching the N+ source region.

The second MESFET, labeled as a high side switch (i.e. with a separate drain and a source shared with the other MESFET of the pair), comprises drain metal 364, drain pad opening 365, Schottky gate metal 360, trench 361, gate interconnect metal 359, and gate pad opening 362. Common metal 357 serves as the source of the non-grounded device of the MESFET pair, functioning as the source of either a high side switch or a synchronous rectifier in the converter. Since the device layout is symmetric, however, the two devices could be reversed so that pad 351 represents D2 and pad 363 represents S1.

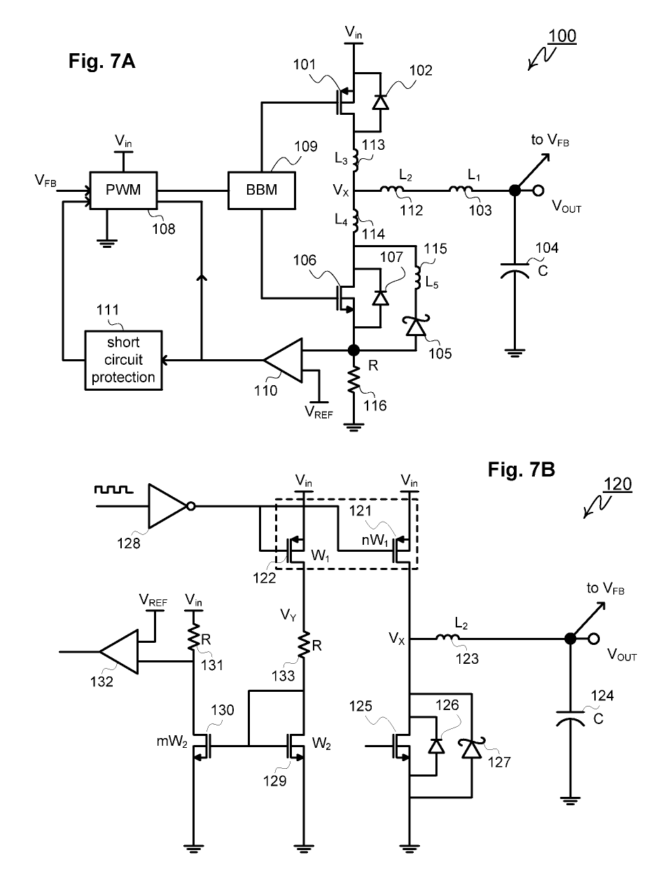

By merging two MESFETs monolithically, parasitic inductance between the devices (as illustrated in circuit 100 of FIG. 7A) is completely eliminated. By eliminating stray inductance, voltage stresses on the power devices is reduced, eliminating the need for over-rating the devices' voltage capabilities. As a result both reliability and efficiency may be improved, in either synchronous buck or synchronous boost topologies.

Merged Power MESFET Pair with Integral Current Sensing

To achieve accurate current sensing, minimal parasitic inductance, and short break-before make timing in a high-frequency push-pull power MESFET half-bridge for DC-to-DC switching converters requires the monolithic integration of not two, but three power MESFETs. As described previously, integration is critical to matching the threshold between the power switch and the current sense device to accurately measure device current in a power MESFET switch (without the need for a current sense resistor). Similarly, the threshold tracking and minimal inductance of an integrated power MESFET pair is important to minimize the break-before-make in a push-pull half bridge, avoiding short through currents and avoiding over-voltage stresses on the switches themselves. Combining power switching and sensing criteria means that both high-side and low-side power half-bridge devices and an integral current sense device must be monolithically integrated.

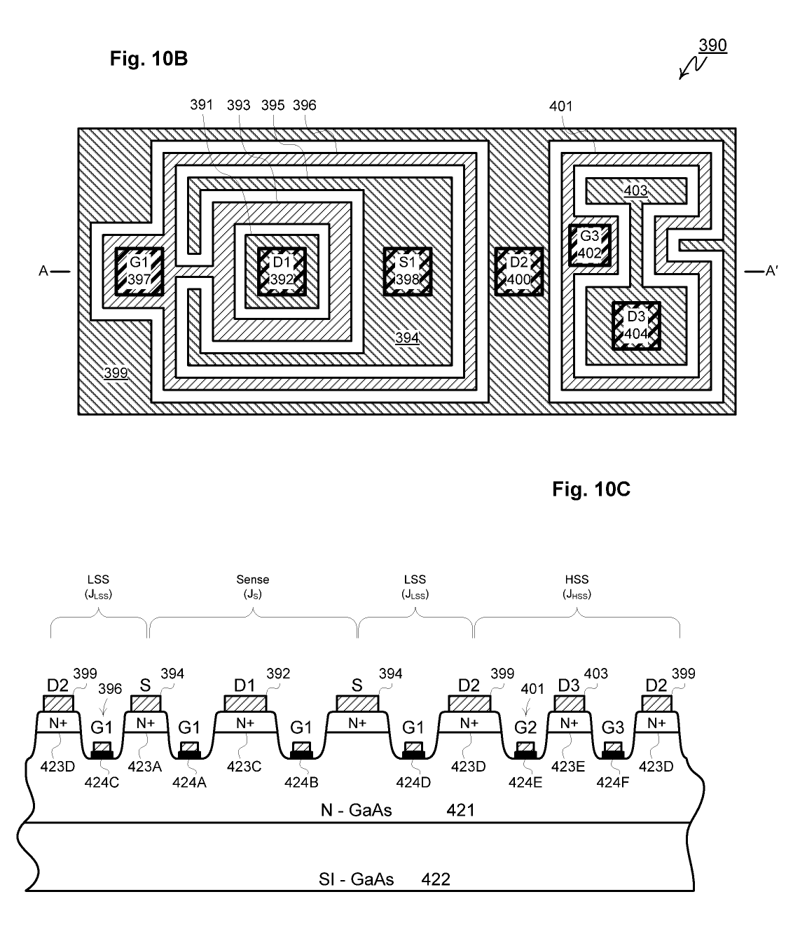

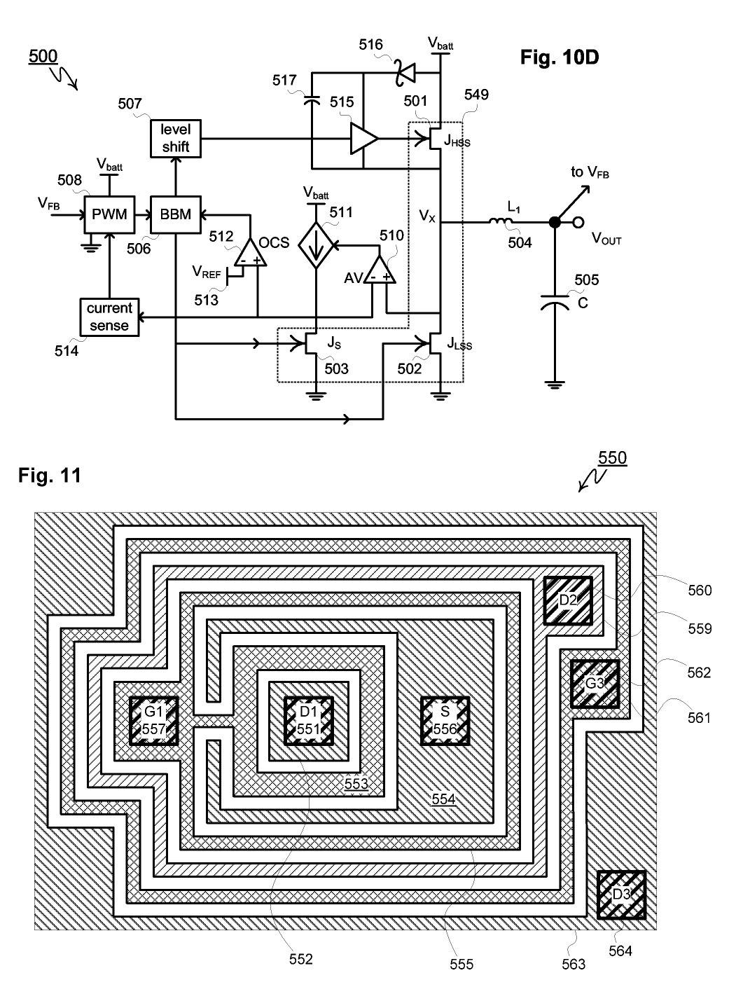

Without the capability of isolation this integration requires a special inventive three-MESFET merged device layout, one example of which is illustrated in FIG. 10A. Specifically circuit 380 comprises a three N-channel MESFET circuit comprising low-side power MESFET 382, high-side (or floating) MESFET 383, and current-sense device 382. In the example shown, low-side switch and sense devices 382 and 381 share a common gate G_{LS} while high-side or floating device 383 has a separate gate G_{HS} distinct from the low side switch. Monolithically integrated, the MESFET matching and low parasitic inductance makes switching power conversion at multi-MHz frequencies feasible.

FIG. 10B illustrates one possible plan view 390 of triple-MESFET merged device combining a MESFET power half-bridge with integral current sensing, thereby monolithically forming circuit 380 without the need for device isolation. In this drawing, the two large-gate-width power MESFETs share a common node 399 with pad opening 400 (labeled D2), which serves as the drain of the low-side device, and the source of the high side device. The low-side power MESFET comprises source metal 394, source pad opening 398, gate and gate metal 396, and gate pad opening 397 (labeled G1). The high-side (or floating) power MESFET comprises gate and gate metal 401, drain metal 403 and drain pad opening 404 (labeled D3). In this layout, the gate comprises the gate metal as shown and also includes the Schottky gate and trench gate structure as previously described (but not shown in the plan view).

Since the two main power MESFETs share one common node, namely metal 399 they can be integrated monolithically without the need for isolation, using a layout similar to the plan view 350 of FIG. 9D.

Contained within (i.e. laterally surrounded by) the low-side power MESFET is the current-sense MESFET comprising drain metal 391 and pad opening 392 (labeled D1). The current sense device shares the same source 394, source pad opening 398, gate and gate metal 396, and gate pad opening 397 as the low-side power MESFET, having a separate drain unique from that of the low-side power MESFET's drain 399.

By surrounding the sense MESFET with the source of the low-side power MESFET (in a layout similar to merged sense device 300 of FIG. 8C) no isolation is needed to integrate the sense device into the merged power MESFET half-bridge. Also by sharing the gate pad opening 397 and a common source 394 and source pad 398, the device is more compact.

FIG. 10C illustrates a cross section of the triple MESFET implementing the merged power MESFET half-bridge with integral current sensing circuit 380. The transistors are denoted herein by the letter j since a MESFET is schematically similar to a JFET having Schottky gate (rather than a PN junction gate). Accordingly, the cross section 420 corresponds to the plan-view layout 390 comprising sense transistor J_{S}, low-side-switch transistor J_{Lss} and floating or high-side switch transistor J_{HSS}.

Sense transistor j_{S} comprises drain D1 having metal 392 and N+ region 423C, gate G1 with Schottky gates 424A and 424B concentrically surrounding and laterally enclosing the drain D1, and further comprising source S having metal 394 with N+ regions 423A and 423B concentrically surrounding and laterally enclosing the gate G1.

Low-side switch J_{LSS} concentrically surrounds and laterally contains the entire sense transistor, located along the outer periphery of the sense transistor J_{S}. Power transistor L_{SS} physically and electrically shares its source electrodes S (comprising metal 394 with N+ regions 423A and 423B) with sense MESFET Jₛ. Ring shaped gate comprising metal 396, trench and Schottky gate 424C and 421 C concentrically surrounds and laterally contains the source S. This gate electrode is also designated as G1 since metal 396 is electrically shorted to both sense and low-side MESFET gates. The entire structure is further surrounded by concentric drain D2 comprising metal 399 and N+ regions 423D.

Drain D2 of the low-side MESFET J_{LSS} also contains and laterally surrounds high-side power MESFET device J_{HSS} where D2 acts as the source of the high-side device and the output of the half-bridge. The high-side device, further comprises ring shaped gate G3 with metal 403 and trench Schottky gate 424E and 424F further concentrically surrounds and laterally contains drain D3 of high-side MESFET, the high-side drain comprising metal 403 and N+ region 423E.

All devices are formed in N-GaAs epitaxial layer 421 sitting atop semi-insulating GaAs substrate 422 which may include an interfacial layer of P-N junctions or sandwich of varying composition material to further suppress substrate leakage. Surrounded by drain D2, the entire merged device may be separated from other dice on a wafer by sawing, without requiring a mesa etch.

It should be understood that concentric rings comprising the gates, source, and drains of the three MESFETs, need not be circular, but can made as a rectangular band or any other closed geometric shape.

FIG. 10D illustrates the application of the merged power MESFET half-bridge with integral current sensing in synchronous Buck converter 500. In this converter, a power MESFET push-pull power driver with integral current sensing 549 is implemented in GaAs, comprising low-side power MESFET J_{LSS} (labeled 503), high-side power MESFET J_{HSS} (labeled 501), and current sense MESFET device J_{S} (labeled 503). The remainder of Buck converter 500 is implemented in a silicon IC. The entire solution requires only two semiconductor “chips” and still achieves superior device matching and current sensing not possible with discrete power devices.

In the example, high side MESFET 501 the current supply from the battery to inductor 504 in accordance with PWM control circuit 508. Power to drive the high-side N-channel gate requires some floating drive scheme to power the gate of MESFET 501 to a voltage above the battery voltage, in this example using a boot strap power supply with bootstrap capacitor 517 boot strap diode 516 and floating buffer 515 referenced to the source of the high side MESFET, that is referenced to switching voltage Vx. MESFET gate drive buffer 515 is not simply a CMOS inverter but includes special circuitry to limit the maximum gate-to-source voltage impressed on MESFET 501 to around 0.4 to 0.7V, and typically to 0.5 volts.

Low side MESFET 502, electrically matched to high-side MESFET 501, is driven out of phase with the high side switch also controlled through PWM control circuit 508. Break before make BBM circuit 506 prevents simultaneous conduction of both low-side and high-side MESFETs 502 and 501. The gate signal to gate buffer 515 is level shifted from the output of BBM circuit 506 through level shifter 507. The low-side gate buffer contained within BBM circuit 506 is not simply an inverter but one that limits the maximum gate drive on the MESFET to around 0.4 to 0.7V, and typically to 0.5 volts, similar to high side buffer 515 except that it is ground referenced, not floating with the output.

Small gate-width MESFET 503, fabricated monolithically with low-side power MESFET 502, has threshold and gain characteristics matched to the larger power device. Current sensing is achieved by measuring the voltage drop across the device (or a sense resistor in series with the device) whenever the drain voltage of large and small MESFETs 502 and 503 are equal or substantially so. In the example shown, controlled current source 511 is powered by op amp 510 to adjust its current until the voltages are forced to be equal (at least within the offset voltage accuracy of the op amp).

Assuming the drain voltage are equal and the gate potentials on the two devices are identical (since they hard wired together as one gate), then the current through the smaller device shall be equal to the gate width ratio of the large and small MESFET's multiplied by the large MESFET's current. This current monitoring may be used for over current protection and shutdown using OCS comparator 512 and voltage reference 513, or to assist in PWM or BBM circuit operation as shown.

Such circuits and devices are inventive since, lacking isolation, matched current source techniques have never for been possible using power MESFETs.

FIG. 11 illustrates the plan view three concentric MESFETs comprising concentric annular bands also representing an alternative layout for integrating an N-channel power MESFET push-pull pair with integrated current sensing.

In geometry 550, drain D1 comprising drain metal 552 represent the inner most device element of the multi-concentric device, surrounded by ring or annular shaped gate metal 553 and corresponding trench Schottky gate (not shown), which in turn is surrounded by ring shaped source S and source metal 554. Drain D1 is contacted through passivation opening 551, gate G1 is contacted through pad opening 557, and source S is contacted through source pad opening 556, together comprising sense transistor J_{S}, the smallest MESFET in the triplet, used for current sensing.

Furthermore, source metal 554 serves as the source for the large gate-width low-side power MESFET switch J_{LSS} including surrounding annular gate metal 555 in turn surrounded by drain metal 559. The Schottky gate metal and trench are not shown for clarities sake but surround the gate metal as in prior examples. Low side power MESFET is contacted through gate pad opening 557 and source pad opening 556, connections electrically shared with current sense MESFET J_{S}. Source metal ring 554 therefore serves as the source metal for both sense MESFET J_{S} on its interior periphery, and low-side power MESFET J_{LSS} on its exterior periphery.

High-side MESFETJHSS surrounds and circumscribes the entire aforementioned structure, where metal 559 acts as the source of the high-side MESFET, surrounded by the annular gate metal 561, which in turn is surrounded by the high side MESFET's annular drain metal 563. Contact to the high-side MESFET is facilitated through the D3 drain pad opening 564, through G3 gate pad opening 562, and through source pad opening 560 (labeled D2 in reference to its use in low-side MESFET J_{LSS}). Metal ring 559 therefore functions as both the source of the high-side power MESFET J_{HSS} and the drain of the low-side power MESFET J_{LSS} simultaneously, completely eliminating any stray source or drain inductance between the two power switches. The inventive current-sensing push-pull power device can be used as a high speed push pull power stage with integral current sensing in both synchronous Boost or synchronous Buck converter applications without the need for any MESFET isolation capability.

What is claimed is:

1. A switching device that comprises:
a substrate;
a first MESFET fabricated on the substrate, the first MESFET including a first gate, a first source, and a first drain; and
a second MESFET fabricated on the substrate, the second MESFET including:
a second gate that is electrically shorted to the first gate;
a second source that is electrically shorted to the first source; and
a second drain that is not electrically shorted to the first drain.

2. The switching device of claim 1 where the gate width of the second MESFET is “n” times larger than the first MESFET.

3. The switching device of claim 2 where the second MESFET is used as a power device and where the smaller second device is used to indirectly monitor the current in the first device.

4. The switching device of claim 2 where n is in the range of 100 to 5000.

5. The switching device of claim 1 where the semiconductor material is gallium arsenide (GaAs).

6. The switching device of claim 1 where the semiconductor material is indium phosphide (InP).

7. A switching device that comprises:
a substrate;
a first MESFET fabricated on the substrate, the first MESFET including a first gate, a first source, and a first drain; and
a second MESFET fabricated on the substrate, the second MESFET having a gate width substantially larger than the first MESFET, the second MESFET including:
a second gate that is electrically shorted to the first gate;
a second source that is electrically shorted to the first source; and
a second drain that is not electrically shorted to the first drain but is held at substantially the same voltage by adjusting the drain current through the first MESFET.

8. The switching device of claim 7 where the drain current in first MESFET is controlled by a differential amplifier comparing the voltage at the drains at the first and second MESFETs.

9. The switching device of claim 7 where the second MESFET comprises the power device in a boost converter.

10. A monolithically-integrated merged dual MESFET comprising a first gate, a first source, a first drain; and a second drain where the first gate laterally surrounds both the first and second drains.

11. The merged dual MESFET of claim 10 where the first gate has a shape that resembles the number eight.

12. The merged dual MESFET of claim 10 where first source surrounds the first gate.

13. A switching device that comprises:
a substrate;
a first MESFET fabricated on the substrate, the first MESFET including a first gate, a first source, and a first drain; and
a second MESFET fabricated on the substrate, the second MESFET including:
a second gate that is not electrically shorted to the first gate;
a second source that is electrically shorted to the first drain at a node V x; and
a second drain.

14. The switching device of claim 13 where the first source is grounded or connected to the negative terminal of a battery, where the second drain is connected to a positive supply voltage or the positive terminal of a the battery, and where an inductor is connected between an output node and the node Vx, and where a filter capacitor is connected between the output node and the ground.

15. The switching device of claim 14 comprising the power stage of a synchronous Buck switching voltage regulator.

16. The switching device of claim 14 where the first and second MESFETs are operated to conduct out of phase so that no more than one of the MESFETs is “on” at the any time.

17. The switching device of claim 14 where the on time of the MESFETs is used to regulate the voltage at the converter output either by varying the switching pulse width or switching frequency.

18. The switching device of claim 14 where a Schottky diode is connected in parallel with the first MESFET, with the Schottky cathode connected to the first drain and the Schottky-anode connected to the first source.

19. The switching device of claim 13 where an inductor is connected between a positive supply voltage or the positive terminal of a the battery and the node Vx, and where the second drain is connected to an output node and where a filter capacitor is connected between the output node and ground.

20. The circuit of claim 19 comprising the power stage of a synchronous boost switching voltage regulator.

21. The switching device of claim 19 where the first and second MESFETs are operated to conduct out of phase so that no more than one of the MESFETs is “on” at the any time.

22. The switching device of claim 19 where the on time of the MESFETs is used to regulate the voltage at the converter output either by varying the switching pulse width or switching frequency.

23. The switching device of claim 19 where a Schottky diode is connected in parallel with the second MESFET, with the Schottky cathode connected to the second drain and the Schottky-anode connected to the second source.

24. The switching device of claim 19 where a Zener diode is connected in parallel with the second MESFET, with the Schottky cathode connected to the first drain and the Schottky-anode connected to the first source.

25. A monolithically-integrated merged dual MESFET comprising a first source, a first gate, a second source, a second gate, and a first drain; where the first gate laterally surrounds the first the source, where the second gate laterally surrounds the second the source, and where the first drain laterally surrounds both first and second gates.

26. The merged dual MESFET of claim 25 where the first drain has a shape that resembles the number eight.

27. A merged MESFET device that comprises:
a substrate;
a first MESFET fabricated on the substrate, the first MESFET including a first gate, a first source, and a first drain;
a second MESFET fabricated on the substrate, the second MESFET including:
a second gate electrically shorted to the first gate,
a second source electrically shorted to the first source, and
a second drain, and
a third MESFET fabricated on the substrate, the third MESFET including:
a third gate,
a third source electrically shorted to the second drain at a node Vx, and
a third drain.

28. The MESFET merged device of claim 27 where the gate width of the second MESFET is substantially larger than the gate width of the first MESFET.

29. The merged MESFET device of claim 28 where the gate width of the second MESFET is 100 to 5000 times larger than that of the first MESFET.

30. The MESFET merged device of claim 27 where the gate width of the second MESFET is substantially similar to the gate width of the third MESFET.

31. The merged MESFET device of claim 30 where the gate width of the second MESFET is 0.33 to 3 times that of the first MESFET.

32. The merged MESFET device of claim 27 where the second and third MESFETs are operated to conduct out of phase so that no more than one of the MESFETs is “on” at the any time.

33. The merged MESFET device of claim 27 where the first MESFET is used to monitor the current in the second MESFET.

34. The merged MESFET device of claim 27 where the second and third MESFETs form a power push-pull driver used to implement a switching voltage regulator in conjunction with an inductor and an output filter capacitor.

35. The merged MESFET device of claim 34 in a step-up synchronous boost converter.

36. The merged MESFET device of claim 34 in a step-down synchronous Buck converter.

37. The merged MESFET device of claim 27 where the first and second sources are grounded or connected to the negative terminal of a battery, where the third drain is connected to a positive supply voltage or the positive terminal of a battery, and where an inductor is connected between an output node and the node Vx, and where a filter capacitor is connected between the output node and the ground or the negative terminal of the battery.

38. The merged MESFET device of claim 37 comprising a synchronous Buck switching voltage regulator.

39. The merged device of claim 27 used in a circuit where the first and second sources are grounded or connected to the negative terminal of a battery, and where an inductor is connected between a positive supply voltage or the positive terminal of a the battery and the node Vx and where the third drain is connected to an output node, and where a filter capacitor is connected between the output node and the ground or the negative terminal of the battery.

40. The merged MESFET device of claim 39 comprising a synchronous boost switching voltage regulator.

41. The merged device of claim 27 where the first MESFET is used to monitor the current in the second MESFET.

42. A monolithically-integrated merged triple MESFET comprising a first source, a first gate, a second gate, and a first, second and third drain; where the first gate laterally surrounds the first the source and also surrounds a first drain, where the first gate is also surrounded by a second drain, which also laterally surrounds a second gate, where the second gate laterally surrounds a third drain.

43. a monolithically-integrated merged triple MESFET comprising
a first gate formed as an inner ring interconnected to an outer ring,
a first drain surrounded by the inner ring of the first gate;
a first source that substantially surrounds the inner ring of the first gate and is substantially surrounded by the outer ring of the first gate;
a second drain that surrounds the first gate;
a second gate that surrounds the second drain; and a third drain that surrounds the second drain.
